(19) United States
(12) Patent Application Publication
(10) Pub. No.: US 2007/0175383 A1
(43) Pub. Date: Aug. 2, 2007

(54) Process for producing single crystal of gallium-containing nitride

(75) Inventors: Tsuguo Fukuda, Miyagi (JP); Ehrentraut Dirk, Miyagi (JP); Akira Yoshikawa, Miyagi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: JAPAN SCIENCE AND TECHNOLOGY AGENCY, Kawaguchi-shi (JP)

(21) Appl. No.: 10/586,581

(22) PCT Filed: Jan. 20, 2005
(86) PCT No.: PCT/JP05/00696

§ 371 Date: Jul. 19, 2006

(30) Foreign Application Priority Data
Jan. 21, 2004 (JP) 2004-013114

(51) Int. Cl. C30B 15/00; C30B 19/00; C30B 21/06

(52) U.S. Cl. 117/35; 117/59; 117/54; 117/60

(57) ABSTRACT

[Problems] To provide a process that allows melt growth of single crystals of a gallium-containing nitride with less dangerous, inexpensive equipment, in particular, a process that can be performed under normal pressure. [Solving Means] A process for producing single crystals of a gallium-containing nitride on a seed crystal substrate by a reaction between molten gallium retained in a container inside a crystal growth chamber and nitrogen gas, the process includes the steps of preparing a eutectic alloy melt of gallium (Ga); dipping the seed crystal substrate into the eutectic alloy melt, the seed crystal substrate having a catalytic metal having a mesh, stripe, or open polka-dot pattern deposited thereon; and graphoepitaxially growing a single crystal phase of the gallium-containing nitride on the surface of the seed crystal substrate by the reaction at the surface of the seed crystal substrate between gallium, which is a component of a eutectic alloy, and nitrogen dissolving into the eutectic alloy melt from a space zone containing a nitrogen supply source above a surface of the melt.

### TECHNICAL FIELD

The present invention relates to a process of growing single crystals of a gallium-containing nitride, such as GaN, AlGaIn, or the like, on a substrate from a melt containing gallium (Ga).

### BACKGROUND

Electrooptic devices to which nitrides such as GaN and AlGaIn are applied have used nitrides grown on sapphire (Al₂O₃) or SiC substrates by heteroepitaxial processes. According to a MOCVD process, which is most commonly used, GaN is grown from a vapor phase. However, this process has disadvantages such as low reaction rate and a large number of dislocations per unit area (about 10⁸/cm² at the minimum); in addition, bulk single crystals cannot be produced by this process.

An epitaxial growth process that uses halide vapor (HVPE) has been suggested (Non-patent documents 1 and 2). According to this process, GaN substrates having a diameter of 2 inches can be produced; however, since the defect density in the surface is about 10⁷ to 10⁹/cm², quality required of laser diodes cannot be sufficiently maintained.

Recently, a melt growth process in which GaN crystals are grown by controlling the conditions, such as temperature and pressure, after a solute is dissolved in a solvent to reach a saturation state has been proposed (Non-patent document 3).

In general, a melt growth process has an advantage over solid-phase reaction processes and vapor-phase deposition process in that high-quality crystals are more easily obtainable. GaN single crystals having a diameter of 6 to 10 mm have been obtained using a melt containing Ga and Mg, Ca, Zn, Be, Cd, or the like by this process (Non-patent document 4 and Patent document 1). However, production of single crystals requires a pressure as high as 2,000 MPa, which poses risk. Moreover, from the industrial viewpoint, putting this process into operation requires very expensive equipment since the process requires ultrahigh pressure devices.

As alternatives to these processes, a process of injecting gas containing nitrogen atoms into a melt of a group III metal (Patent document 2) and a process of producing crystals of a group III nitride by reacting a melt of a group III metal with nitrogen-containing gas at a relatively low pressure by using a solvent such as Na (Patent document 3) are known.

Non-patent document 1: M. K. Kelly, 0. Ambacher “Optical patterning of GaN films”, Appl. Phys. Lett. 69, (12), (1996)

Non-patent document 2: W. S. Wrong, T. Samds “Fabrication of thin-film InGaN light-emitting diode membranes”, Appl. Phys. Lett. 75 (10) (1999)

Non-patent document 3: Inoue et al., “Journal of the Japanese Association for Crystal Growth Cooperation (JACG)” 27, p. 54 (2000)

Non-patent document 4: S. Porowski “Thermodynamical properties of III-V nitrides and crystal growth of GaN at high N2 pressure”, J. Cryst. Growth, 178 (1997), 174-188

Patent document 1: U.S. Pat. No. 6,273,948 B1 (PCT Japanese Translation Patent Publication No. 2002-513375)

Patent document 2: U.S. Pat. No. 6,270,569 B1 (Japanese Unexamined Patent Application Publication No. 11-189498)

Patent document 3: U.S. Pat. No. 6,592,663 B1 (Japanese Unexamined Patent Application Publication No. 2001-64098)

### DISCLOSURE OF THE INVENTION

Problems to be Solved by the Invention

An object of the present invention is to provide a process that allows melt growth of single crystals of a gallium-containing nitride with less dangerous, inexpensive equipment, in particular, a process that can be performed under normal pressure.

Means for Solving the Problems

A process of the present invention is a process of growing single crystals of a gallium-containing nitride on a seed crystal substrate by a graphoepitaxial method.

That is, the present invention provides: (1) a process for producing single crystals of a gallium-containing nitride on a seed crystal substrate by a reaction between molten gallium retained in a container inside a crystal growth chamber and nitrogen gas, the process comprising preparing a eutectic alloy melt of gallium (Ga); dipping the seed crystal substrate into the eutectic alloy melt, the seed crystal substrate having a catalytic metal having a mesh, stripe, or open polka-dot pattern deposited thereon; and graphoepitaxially growing a single crystal phase of the gallium-containing nitride on the surface of the seed crystal substrate by the reaction at the surface of the seed crystal substrate between gallium, which is a component of a eutectic alloy, and nitrogen dissolving into the eutectic alloy melt from a space zone containing a nitrogen supply source above a surface of the melt.

The present invention also provides: (2) the process for producing the single crystals of the gallium-containing nitride according to item (1), wherein the catalytic metal is platinum (Pt) and/or iridium (Ir).

The present invention also provides: (3) the process for producing the single crystals of the gallium-containing nitride according to item (1), wherein at least one metal selected from the group consisting of aluminum, aluminum (Al), indium (In), ruthenium (Ru), rhodium (Rh), palladium (PD), rhenium (Re), osmium (Os), bismuth (Bi), and gold (Au) forms the eutectic alloy melt with gallium (Ga).

The present invention also provides: (4) the process for producing the single crystals of the gallium-containing nitride according to item (1), wherein the pressure in the space zone containing the nitrogen supply source is 0.1 to 0.15 MPa.

The present invention also provides: (5) the process for producing the single crystals of the gallium-containing nitride according to item (1), wherein the nitrogen supply source is nitrogen, NH₄, or nitrogen-containing compound gas.

The present invention also provides: (6) the process for producing the single crystals of the gallium-containing nitride according to item (1), wherein the seed crystal substrate is sapphire single crystals.

The present invention also provides: (7) the process for producing the single crystals of the gallium-containing nitride according to item (1), wherein the seed crystal substrate has a crystal layer composed of a nitride including at least gallium (Ga), aluminum (Al), or indium (In).

The present invention also provides: (8) the process for producing the single crystals of the gallium-containing nitride according to item (1), wherein a single crystal thin film of a gallium-containing nitride represented by AlₓGa_{1-x-y}In_{y}N (0<x<1, 0<y<1, 0<x+y<1) is grown from the eutectic alloy melt of gallium or by further dissolving aluminum (Al) and indium (In) in Ga.

The present invention also provides: (9) the process for producing the single crystals of the gallium-containing nitride according to item (1), wherein the seed crystal substrate is attached to a lower end portion of a rotating/vertical drive shaft and crystals are grown while rotating the seed crystal substrate.

The present invention also provides: (10) the process for producing the single crystals of the gallium-containing nitride according to item (1), wherein the crystal growth chamber is of a vertical type in which at least two temperature zones with different temperatures in the vertical direction of the chamber are formed, and the seed crystal substrate is pulled up by the vertical drive shaft to position the seed crystal substrate in a low-temperature zone to allow crystals to grow.

According to the graphoepitaxial method used in the present invention, a regularly ordered pattern is provided to the surface of a substrate, and single crystals are produced from crystal nuclei, i.e., seeds, regularly aligned due to the pattern. In the past, practical examples of the graphoepitaxy by vapor- or liquid-phase methods have been disclosed mainly for controlled-orientation crystal growth of organic thin films or orientation-controlled growth of liquid crystals on SiO₂ amorphous substrates (I. Smith, D C. Flanders, Appl. Phys. Lett. 32, (1978), 349; H I. Smith, M W. Geis, C V. Thompson, H A. Atwater, J. Cryst. Growth, 63, (1983), 527; T. Kobayashi, K. Takagi, Appl. Phys. Lett. 45, (1984), 44; D C. Flanders, D C. Shaver, H I. Smith, Appl. Phys. Lett. 32, (1978), 597 [Liquid crystal]). However, the graphoepitaxial method is also useful for nitride thin films, crystal growth rate of which is highly dependent on orientation.

Advantages

According to the present invention, the defect density, which is the problem associated with a GaN substrate of an epitaxial growth process that uses halide vapor (HVPE process) (about 10⁷ to 10⁹/cm²), can be reduced to about 10⁴/cm² or less, and qualities required for increasing the intensity of LEDs for white light and qualities required of laser diodes can be sufficiently maintained. Moreover, in addition to applications to bulk devices, a broader range of application is possible as substrates. Furthermore, since high pressure is not required in supplying nitrogen gas, the facility therefor is practical even from the viewpoint of industrial production. cl BEST MODE FOR CARRYING OUT THE INVENTION

According to the process of the present invention, single crystals of a gallium-containing nitride are grown on a substrate from a Ga-containing melt by graphoepitaxy. The Ga-containing melt is a melt of a eutectic alloy of gallium. This eutectic alloy melt serves as a solvent when nitrogen in a space zone, which is above the surface of the eutectic alloy melt and which contains a nitrogen supply source, dissolves into the melt. Single crystals of a gallium-containing nitride are grown on a seed crystal substrate, which has a catalytic metal deposited thereon, by the reaction between Ga and nitrogen dissolved in the eutectic alloy melt retained in a container inside a crystal growth chamber that can be heated from around.

In order to reduce the defects such as etch-pits in the single crystals, the seed crystal substrate preferably has a lattice constant close to that of single crystals of the gallium-containing nitride. Examples of such a substrate include sapphire, SiC, ZnO, and LiGaO₂. A substrate including a crystal layer having substantially the same structure and substantially the same lattice constant as those of the composition to be grown by homoepitaxy is preferable. For example, a substrate having a crystal layer of a nitride at least containing gallium, aluminum, or indium is preferable.

The gallium-containing compound used as a gallium supply source of the eutectic alloy melt is mainly composed of a gallium-containing nitride or its precursor. For example, a gallium-containing azide, amide, amide-imide, imide, hydride, intermetallic compound, or alloy may be used as the precursor.

The metal that forms the eutectic alloy with Ga is at least one metal selected from aluminum (Al), indium (In), ruthenium (Ru), rhodium (Rh), palladium (Pd), rhenium (Re), osmium (Os), bismuth (Bi), and gold (Au).

Al, In, Ru, Rh, Pd, Re, Os, and Au are all transition metals. None of these undergoes a reaction that forms a nitride with a group III element such as Ga. Al and In are each a constitutional element of the Ga-containing nitride compound, and the purity can be increased since the constituent element itself functions as a solvent (self flux). Although Bi is a representative metal of the same group as nitrogen, Bi does not undergo the reaction for forming a nitride with a group III element such as Ga. These metals that constitute the eutectic alloy with Ga decrease the temperature at which the nitride dissolves (temperature of crystallization) to about 800° C. to 900° C.

The solubility of nitrogen in the eutectic alloy melt is preferably as high as possible. The solubility of nitrogen depends on the composition ratio of the eutectic alloy. As for this composition ratio (molar ratio), the ratio of the metal constituting the eutectic alloy to Ga is about 1:3 to 7, preferably 1:4 to 5. The solubility of nitrogen decreases outside this range.

Specific examples of binary eutectic alloy compositions are as follows: Ga₁₋ₓAlₓ, Ba₁₋ₓInₓ, Ga₁₋ₓRuₓ, Ga₁₋ₓRhₓ, Ga₁₋ₓPdₓ, Ga₁₋ₓReₓ, Ga₁₋ₓOsₓ, Ga₁₋ₓBiₓ, and Ga₁₋ₓAuₓ (0<x<1, preferably, 0.3<x<0.8, and more preferably 0.5<x<0.7).

Specific examples of ternary eutectic alloy compositions are as follows: Ga_{1-x-y}RuₓRh_{y}, Ga_{1-x-y}RuₓPd_{y}, Ga_{1-x-y}RuₓRe_{y}, Ga_{1-x-y}RuₓOs_{y}, Ga_{1-x-y}RuₓBi_{y}, Ga_{1-x-y}RuₓAu_{y}, Ga_{1-x-y}RhₓPd_{y}, Ga_{1-x-y}RhₓRe_{y}, Ga_{1-x-y}RhₓOs_{y}, Ga_{1-x-y}RhₓBi_{y}, Ga_{1-x-y}RhₓAu_{y}, Ga_{1-x-y}PdₓRe_{y}, Ga_{1-x-y}PdₓOs_{y}, Ga_{1-x-y}PdₓBi_{y}, Ga_{1-x-y}PdₓAu_{y}, Ga_{1-x-y}ReₓOs_{y}, Ga_{1-x-y}ReₓBi_{y}, Ga_{1-x-y}ReₓAu_{y}, Ga_{1-x-y}OsₓBi_{y}, Ga_{1-x-y}OsₓAu_{y}, and Ga_{1-x-y}BiₓAu_{y} (0<x<1, 0<y<1, preferably, 0.3<x<0.7, 0.3<y<0.7).

For example, in order to grow crystals of AlₓGa_{1-x-y}In_{y}N (0<x<1, 0<y<1, 0<x+y<1), a eutectic alloy of Al—Ga—In or a melt containing Al and In as solutes and a eutectic alloy of Ga and an element other than Al and In is used. A commercially available nitride, such as a solid solution of AlN—GaN—InN or its amide [(Ga,Al,IN)Cl₃(NH₃)₆] prepared by a vapor phase process may be used as the melt.

In order to prepare such a eutectic alloy melt, necessary ingredients are prepared at appropriate ratios such that the ratio of the metal that forms the eutectic alloy with Ga and the ratio of the Ga supply source are set as desired. The ingredients are placed in a reactor and heated and melted in the reactor at a temperature 100° C. to 150° C. higher than the eutectic temperature (this temperature corresponds to the temperature of crystallization of the single crystals of the nitride during the process of cooling). Through this overheating to a temperature higher than the eutectic temperature, a larger amount of nitrogen can be dissolved in the melt. However, at an excessively high temperature, undesirable phenomenon, such as evaporation of the solvent component, may occur. As a result of the overheating, the melt moves sufficiently and thus is uniformly distributed on the catalytic surface.

The substrate having seed crystals deposited thereon as the catalyst is dipped in the eutectic alloy melt, and a single crystal phase of a gallium-containing nitride is grown on the seed crystal substrate surface through a reaction, which is carried on at the seed crystal substrate surface, between gallium and nitrogen dissolving into the melt from the space zone which is above the surface of the eutectic alloy melt and which contains a nitrogen supply source.

As the catalytic metal deposited on the seed crystal substrate, platinum (Pt) and/or iridium (Ir) is preferably used. FIG. 1 includes a schematic plan views showing a graphoepitaxial method that uses a catalytic metal. FIG. 2 shows the concept of the process of growing single crystals of a gallium-containing nitride on a seed crystal substrate through the reaction between nitrogen gas and molten gallium retained in the container inside the crystal growth chamber. As shown in FIG. 1(A), a catalyst 2 is preferably deposited such that it covers a single crystal substrate 1 by forming a mesh pattern, stripe pattern, or open polka-dot pattern. The possible width of the mesh or stripe is about 5 μm to about 500 μm, preferably about 50 μm to 70 μm.

The atmosphere in the space zone above the eutectic alloy melt and containing the nitrogen supply source is N₂ gas only, NH₃ gas only, or a mixed gas of N₂ and NH₃ (mixing ratio N:NH₃=1−x:x (0<x<1, preferably 0.05<x<0., and more preferably 0.15<x<0.25). During the synthesis of single crystals of a Ga-containing nitride, the pressure of the atmosphere can be normal but is preferably slightly higher than the normal pressure in order to prevent countercurrent of external air (air, moisture, etc.) into the chamber. In particular, the pressure is about 0.1 to 0.15 MPa, preferably 0.1 to 0.11 MPa.

When a nitrogen compound such as GaN or GaCl₃(NH₃)₆ is used as the material of the gallium supply source of the melt, nitrogen in the material can also serve as the nitrogen supply source.

As shown in FIG. 2, when the seed crystal substrate 1 is dipped in a melt 5 retained at the eutectic temperature, heat escapes by a rotating/vertical drive shaft 14 of the seed crystal substrate 1, thereby decreasing the temperature of the surface of the seed crystal substrate 1 to the temperature of crystallization. As a result, as shown in FIG. 1(B), a nitride 3 grown by graphoepitaxy is formed along the catalyst 2. As shown in FIG. 1(C), Ga-containing nitride single crystals 4 are grown to provide entire coverage, thereby making single crystals of a Ga-containing nitride having a thickness of about 100 to 200 μm.

The temperature of crystallization is 500° C. to 900° C., preferably 600° C. to 750° C. High-quality single crystals can be obtained by setting the temperature distribution to be uniform such that the temperature difference in the horizontal direction of the eutectic alloy melt inside the chamber is within ±5° C./cm and by setting the temperature difference between the melting zone and the crystallization zone to within a range in which sufficient transportation of the Ga source and nitrogen can be ensured in the melt. In order to make the temperature distribution uniform in the plane of the seed crystal substrate and to allow uniform growth of single crystals of a gallium-containing nitride, it is preferable to suspend the seed crystal substrate in the vertical direction from the lower end of the rotation/vertical drive shaft and to rotate the suspended substrate at about 10 to 50 rpm.

The gallium-containing nitride can contain a donor, an acceptor, or a magnetic or optically active dopant. Excess electrons can be produced by solid-dissolving an element (donor), such as Zn, having a valency smaller than that of gallium at the site of the gallium. An electron-deficient state can be produced by solid-dissolving an element (acceptor), such as Ge, having a valency greater than that of gallium at the site of gallium. The magnetism can be imparted by the incorporation of magnetic ions, such as Fe, Ni, Co, Mn, or Cr ions, as mix crystals. Optical activity can be imparted by using a trace amount of a rare earth metal as a dopant.

FIG. 3 is a diagram showing a structural illustration of a crystal growth system that uses a three-zone liquid phase epitaxy (LPE) furnace preferable for implementing the process of the present invention. Referring to FIG. 3, a melt of a Ga-containing eutectic alloy is contained in a crucible 13 placed on a heat insulator 12 inside a quartz chamber 11. Heaters H1, H2, and H3, etc., which are independently operable, are disposed around the quartz chamber 11 so that they align in the vertical direction to form a multistage system for producing zones with different temperatures in the vertical direction of the quartz chamber 11. The heaters are set such that the temperature is the lowest at the top and increases toward the bottom.

The temperature of the melt is controlled such that the melt in the upper end portion of the crucible 13 is slightly higher than the temperature of the crystallization. This promotes convective flow of the melt and thus can allow the solute, Ga, to be uniformly distributed in the melt. The thickness of the heat insulator in the furnace is increased to prevent heat dissipation and to maintain the temperature, and intervals of turns and the diameters of kanthal lines of the heaters are adjusted to realize a uniform temperature distribution in the horizontal direction in the quartz chamber 11. The temperature is preferably maintained such that the temperature distribution is within ±5° C. per centimeter of the distance from the inner wall surface of the chamber toward the central axis line of the chamber.

The seed crystal substrate 1 is held by the rotating/vertical drive shaft 14 such that the seed crystal substrate 1 is in contact with the gas-liquid interface, which is the border region between the gas and the melt in the crucible 13. In FIG. 3, a plurality of seed crystal substrates are arranged concentrically and suspended from the rotating/vertical drive shaft 14. At the beginning of the crystal growth, the seed crystal substrates 1 are positioned in the low-temperature zone. The rotating/vertical drive shaft 14 of the seed crystal substrates 1 is connected to the exterior via a cover 15 at the top of the quartz chamber 11, and the position of the seed crystal substrates 1 are changeable from the exterior. In other words, the rotating/vertical drive shaft 14 of the seed crystal substrates 1 has a structure in which the position of the substrates is changeable from the exterior so that the seed crystal substrates 1 and the gallium-containing nitride crystals grown thereon can be pulled up.

The nitrogen material as atmosphere gas can be supplied to a space zone 21 (FIG. 2) containing the nitrogen supply source inside the quartz chamber 11 from outside the quartz chamber 11 through a nitrogen gas feed pipe 16. In order to adjust the nitrogen pressure inside the quartz chamber 11 at this stage, a pressure controlling mechanism is provided. This pressure controlling mechanism includes, for example, a pressure indicator 17 and a gas-feeding valve 18.

An evacuation system (not shown) that can decrease the pressure to 10⁻⁶ Torr to remove air, residual moisture, and the like from the quartz chamber 11 before introduction of nitrogen gas into the space zone 21 containing the nitrogen supply source in the quartz chamber 11 is provided.

In principle, the crystal growth system shown in FIG. 3 allows crystals of a Ga-containing nitride to grow in the crucible 13 from the eutectic alloy melt of Ga and the nitrogen material. By moving the rotating/vertical drive shaft 14 of the seed crystal substrates 1 while controlling the atmosphere, the region where the seed crystal substrates 1, the melt, and the nitrogen material come into contact can be shifted.

In the crucible 13, the eutectic alloy melt of Ga reacts with the nitrogen material and crystals of a Ga-containing nitride are grown from the seed crystal substrates 1 serving as nuclei. By moving the rotating/vertical drive shaft 14 of the seed crystal substrates 1 at a rate of about 0.05 to 0.1 mm/hour, the temperature of the seed crystal substrates 1 decreases because of the temperature differences in the vertical direction in the quartz chamber 11 and heat dissipation from the rotating/vertical drive shaft 14 to which the seed crystal substrates are fixed. As a result, single crystals of a gallium-containing nitride are selectively grown on the surfaces of the seed crystal substrates 1. Furthermore, as the seed crystal substrates 1 and the Ga-containing nitride crystals deposited around the seed crystal substrates 1 move, larger single crystals of the Ga-containing nitride can be grown. In other words, since the region in which the seed crystal substrates 1 comes into contact with the melt and the nitrogen material moves, the region where crystals grown also moves, thereby leading to growth and growth in size of Ga-containing nitride single crystals. During the process, the single crystals of the Ga-containing nitride mainly grow at the gas-liquid interface.

In particular, under the condition where there is enough Ga, nitrogen is continuously supplied into the melt due to the nitrogen gas-dissolving effect of the eutectic alloy of Ga, single crystals of the Ga-containing nitride can be continuously grown by the effect of the catalytic metal, and it becomes possible to grow single crystals of the Ga-containing nitride to a desired size.

### EXAMPLE 1

1. A three-zone liquid phase epitaxy (LPE) furnace was used. A crucible was used as a reactor, and Ga as a solute and solvent metals (Bi:Rh:Pd=1:1:1 based on mole) at a molar ratio of 4:1 were placed in the crucible.

2. Platinum (Pt), i.e., the catalyst, arranged in a mesh pattern was disposed on the surface of a 5 mm×5 mm×0.5 mm (thickness) seed crystal substrate composed of sapphire single crystals. The width of the line of the mesh was 0.1 mm and the gap was 0.1 mm.

3. The interior of the quartz chamber was vacuumed (approximately up to 10⁻⁵ Torr) using a rotary pump and a diffusion pump, and high-purity N₂ gas (99.9999%) was introduced to control the pressure to about p.11 MPa (a slightly positive pressure to prevent countercurrent). The temperature distribution inside the quartz chamber was controlled to ±3° C./cm in the horizontal direction to achieve high uniformity.

4. The temperature was increased to a reaction temperature of 800° C. (about 100° C. to 150° C. higher than the temperature of crystallization) in about 3 hours.

5. The seed crystal substrate with the Pt mesh was dipped in a eutectic alloy melt while rotating the substrate at 30 rpm.

6. The furnace was gradually cooled to a temperature of crystallization (650° C.) in about 10 hours by controlling the temperature with a temperature regulator of the furnace while carrying out the reaction, thereby achieving slow cooling.

7. Upon completion of the reaction, the seed crystal substrate with the Pt mesh was pulled out from the eutectic alloy melt at a pulling rate of 0.05 mm/hour while rotating the seed crystal substrate.

8. The whole furnace was cooled in about 10 hours.

9. The substrate onto which crystals were grown was discharged from the furnace.

FIG. 4 shows results of powder X-ray diffraction of GaN obtained, and FIG. 5 shows the half width of a rocking curve. The crystals were GaN, and the thickness was 100 to 200 μm. For the crystallinity, the half width of the rocking curve was about one third of that of GaN prepared by a CVD process, which showed that the crystals obtained were good single crystals. The defect density in the surface was about 2×10⁴/cm².

### EXAMPLE 2

1. A three-zone liquid phase epitaxy (LPE) furnace was used. A crucible was used as a reactor, and Ga as a solute and solvent metals (Bi:Rh:Pd=1:1:1 based on mole) at a molar ratio of 4:1 were placed in the crucible.

2. Iridium (Ir), i.e., the catalyst, arranged in a mesh pattern was disposed on the surface of a 5 mm×5 mm×0.5 mm (thickness) seed crystal substrate composed of sapphire single crystals (Al₂O₃). The width of the line of the mesh was 0.1 mm and the gap was 0.1 mm.

3. The interior of the chamber was vacuumed (approximately up to 10⁻⁵ Torr) using a rotary pump and a diffusion pump, and high-purity N₂ gas (99.9999%) was introduced to control the pressure to about 0.11 MPa (a slightly positive pressure to prevent countercurrent). The temperature distribution inside the chamber was controlled to ±3° C./cm in the horizontal direction to achieve high uniformity.

4. The temperature was increased to a reaction temperature of 750° C. (about 100° C. to 150° C. higher than the temperature of crystallization) in about 3 hours.

5. The seed crystal substrate with a Pt mesh was dipped in a eutectic alloy melt while rotating the substrate at 50 rpm.

6. The furnace was gradually cooled to a temperature of crystallization (600° C.) in about 10 hours by controlling the temperature with a temperature regulator of the furnace while carrying out the reaction.

7. Upon completion of the reaction, the seed crystal substrate with the Pt mesh was pulled out from the eutectic alloy melt at a pulling rate of 0.05 mm/hour while rotating the seed crystal substrate.

8. The whole furnace was cooled in about 10 hours.

9. The substrate onto which crystals were grown was discharged from the furnace.

FIG. 6 shows results of powder X-ray diffraction of GaN obtained, and FIG. 7 shows the half width of a rocking curve. The crystals obtained were GaN, and the thickness was 100 to 200 μm. For the crystallinity, as in EXAMPLE 1, the half width of the rocking curve was about one third of that of GaN prepared by a CVD process, which showed that the crystals obtained were good single crystals. The defect density in the surface was about 3×10⁴/cm².

### EXAMPLE 3

1. A three-zone liquid phase epitaxy (LPE) furnace was used. A crucible was used as a reactor, and Ga and Al (Ga:Al=4:1 based on mole) as solutes and solvent metals (Bi:Rh:Pd=1:1:1 based on mole) at a molar ratio of 4:1 were placed in the crucible.

2. Iridium (Ir), i.e., the catalyst, arranged in a mesh pattern was disposed on the surface of 5 mm×5 mm×0.5 mm (thickness) seed crystal substrate composed of sapphire single crystals (Al₂O₃). The width of the line of the mesh was 0.1 mm and the gap was 0.1 mm.

3. The interior of the chamber was vacuumed (approximately up to 10⁻⁵ Torr) using a rotary pump and a diffusion pump. Subsequently, high-purity N₂ gas (99.9999%) and high-purity NH₃ gas (99.9999%) at a ratio of 4:1 were introduced to control the pressure to about 0.11 MPa (a slightly positive pressure to prevent countercurrent). The temperature distribution inside the chamber was controlled to ±3° C./cm in the horizontal direction to achieve high uniformity.

4. The temperature was increased to a reaction temperature of 800° C. (about 100° C. to 150° C. higher than the temperature of crystallization) in about 3 hours.

5. The seed crystal substrate with a Pt mesh was dipped in a eutectic alloy melt while rotating the substrate.

6. The furnace was gradually cooled to a temperature of crystallization (700° C.) in about 10 hours by controlling the temperature with a temperature regulator of the furnace while carrying out the reaction.

7. Upon completion of the reaction, the seed crystal substrate with the Pt mesh was pulled out from the eutectic alloy melt at a pulling rate of 0.05 mm/hour while rotating the seed crystal substrate.

8. The whole furnace was cooled in about 10 hours.

9. The substrate onto which single crystals were grown was discharged from the furnace.

FIG. 8 shows results of powder X-ray diffraction of GaN obtained, and FIG. 9 shows the half width of a rocking curve. The crystals obtained were Al_{0.18}Ga_{0.82}N, and the thickness was 100 to 200 μm. For the crystallinity, as in EXAMPLE 1, the half width of the rocking curve was about one third of that of GaN prepared by a CVD process, which showed that the crystals obtained were good single crystals. The defect density in the surface was about 7×10³/cm².

### COMPARATIVE EXAMPLE 1

Crystals were grown under the same conditions as in EXAMPLE 1 except that the melt of Ga alone was used. Ga recrystallized to give deposits. FIG. 10 shows a powder X-ray diffraction diagram of the deposits. The reaction for obtaining GaN did not proceed, and metallic Ga was detected. All peaks were attributable to Ga.

### COMPARATIVE EXAMPLE 2

Crystals were grown under the same conditions as in EXAMPLE 1 except that the catalytic metal was not disposed on the seed crystal substrate. The reaction was extremely slow, and GaN crystallized into powdery substance to give deposits. FIG. 11 shows a powder X-ray diffraction diagram of the deposits. Since reaction for the crystal growth was slow, the crystallization did not progress completely, and a rather broad peak was obtained.

### BRIEF DESCRIPTION OF THE DRAWINGS

FIG. 1 is a schematic diagram showing the process of crystal growth according to the process of the present invention.

FIG. 2 is a schematic diagram of a process for growing single crystals of a gallium-containing nitride on a seed crystal substrate by the reaction between the molten gallium retained in the container inside the crystal growth chamber and nitrogen gas.

FIG. 3 is a schematic diagram of an apparatus used to obtain single crystals of gallium-containing nitride by a melt growth process of the present invention.

FIG. 4 is a powder X-ray diffraction diagram of GaN obtained in EXAMPLE 1.

FIG. 5 is a graph showing the half width of a rocking curve of GaN obtained in EXAMPLE 1.

FIG. 6 is a powder X-ray diffraction diagram of GaN obtained in EXAMPLE 2.

FIG. 7 is a graph showing the half width of a rocking curve of GaN obtained in EXAMPLE 2.

FIG. 8 is a powder X-ray diffraction diagram of GaN obtained in EXAMPLE 3.

FIG. 9 is a graph showing the half width of a rocking curve of GaN obtained in EXAMPLE 3.

FIG. 10 is a powder X-ray diffraction diagram of deposits obtained in COMPARATIVE EXAMPLE 1.

FIG. 11 is a powder X-ray diffraction diagram of deposits obtained in COMPARATIVE EXAMPLE 2.

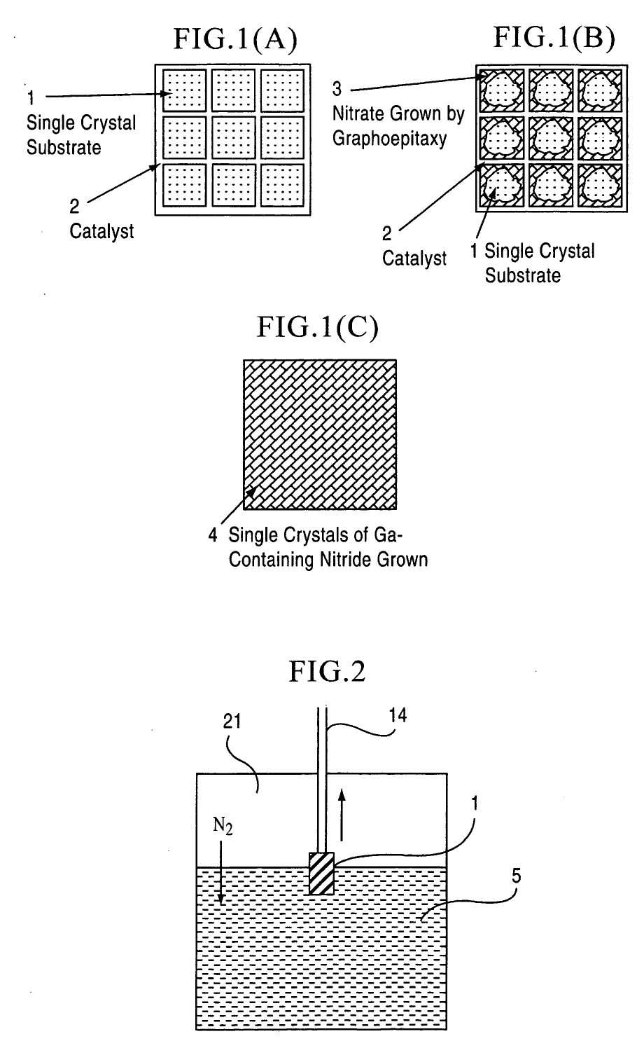

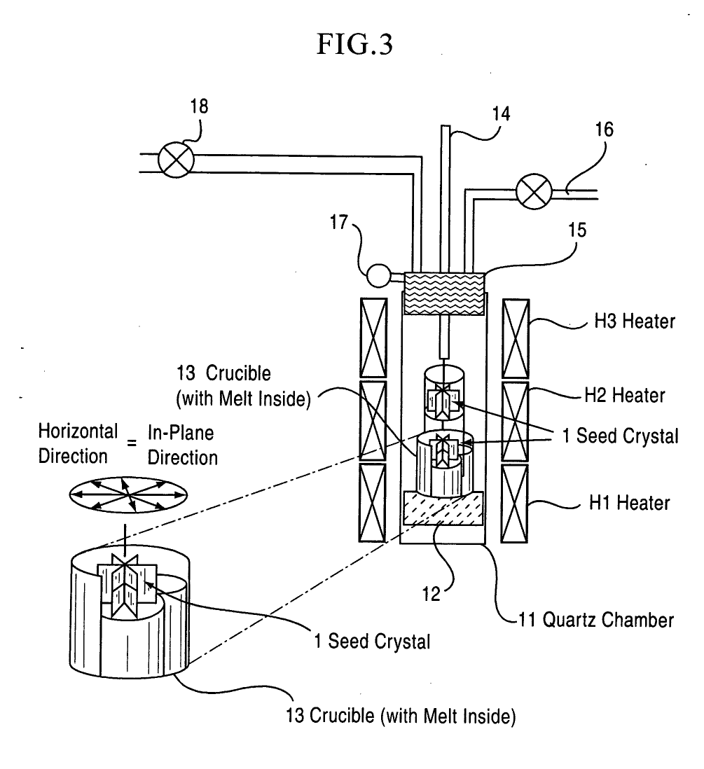

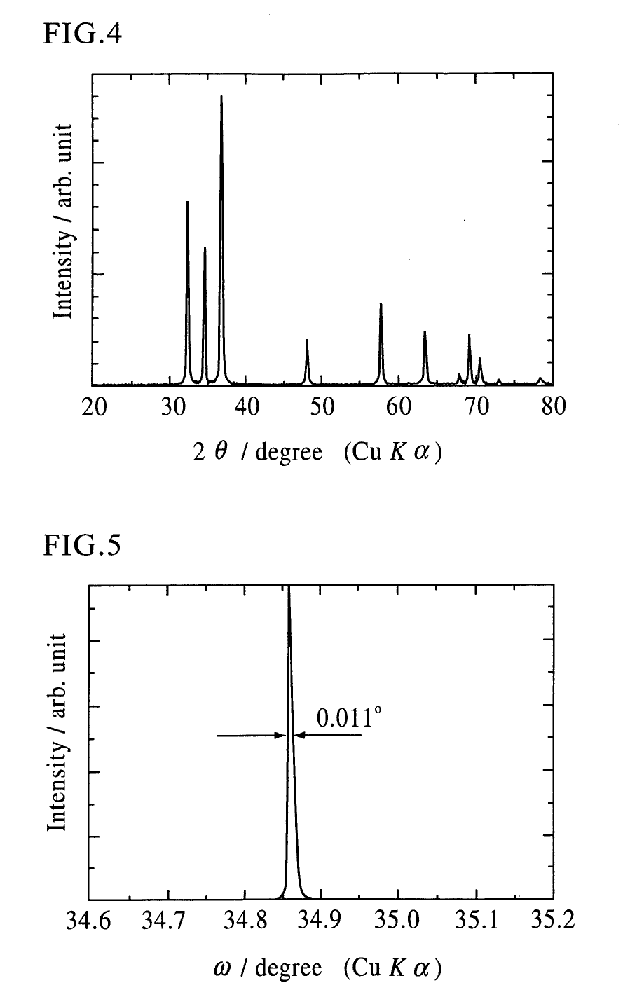

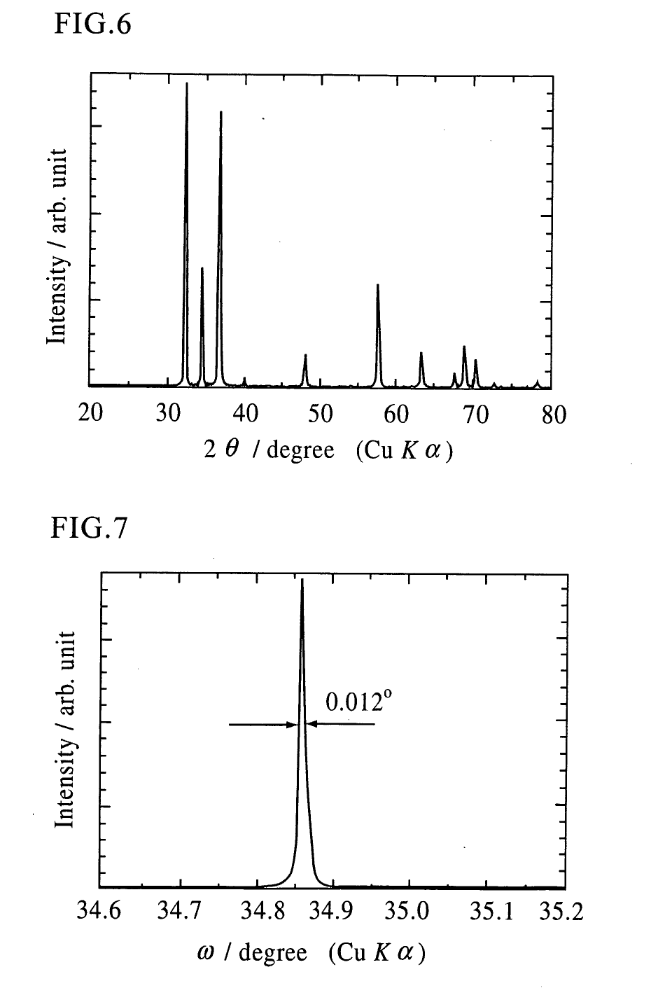

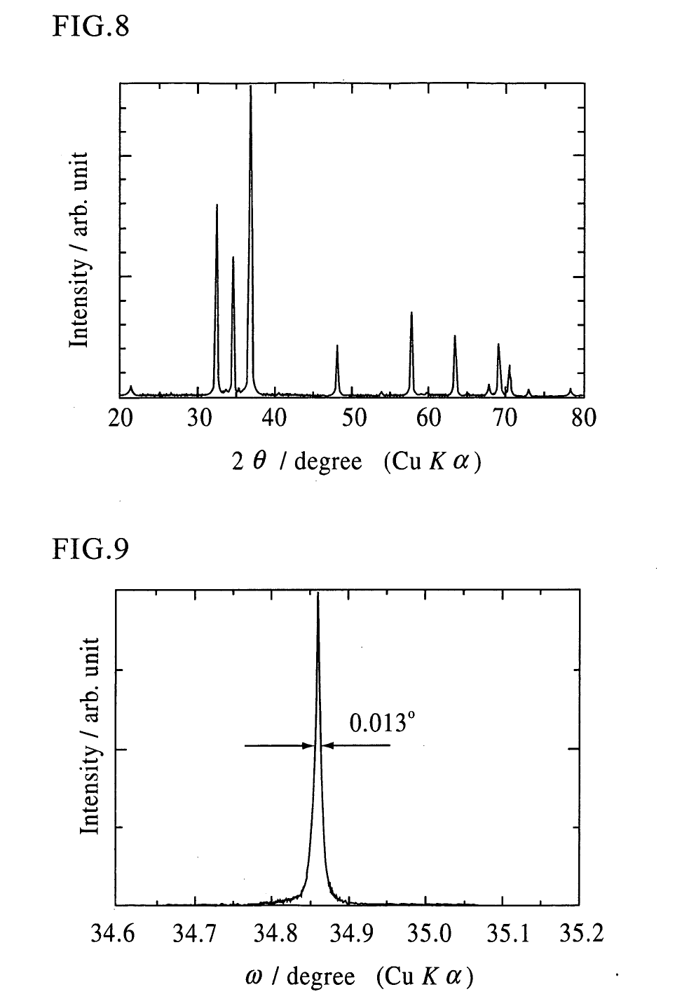

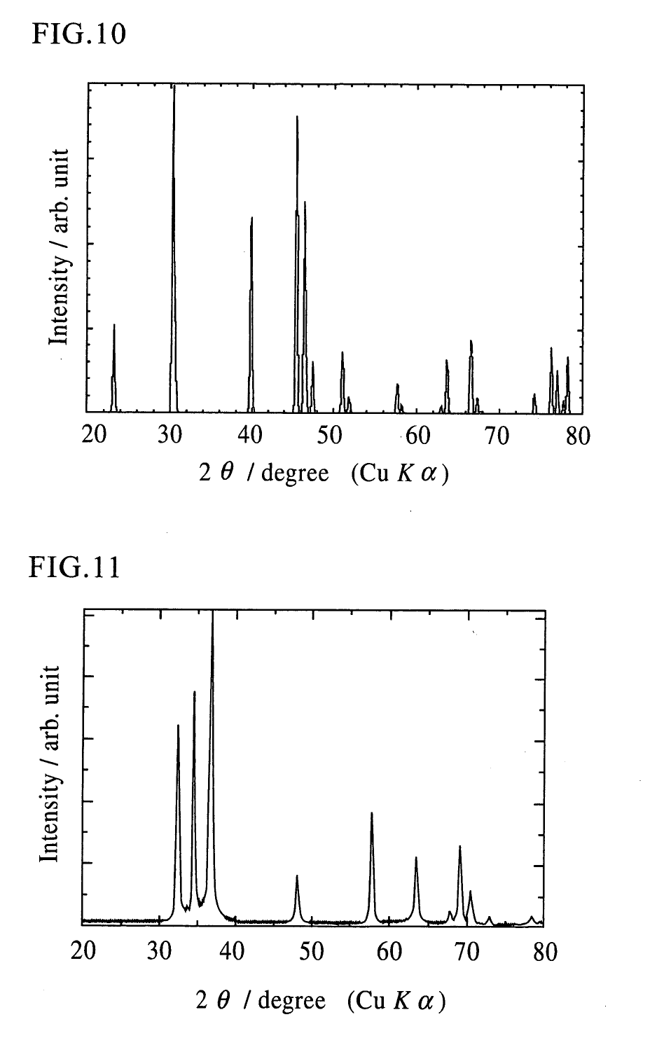

### REFERENCE NUMERALS

1: single crystal substrate

2: catalyst

3: nitride grown by graphoepitaxy

4: single crystals of Ga-containing nitride grown

5: melt

12: heat insulator

14: rotating/vertical drive shaft

15: cover

16: nitrogen gas feed pipe

17: pressure indicator

18: gas-feeding valve

21: space zone containing a nitrogen supply source

1. A process for producing single crystals of a gallium-containing nitride on a seed crystal substrate by a reaction between molten gallium retained in a container inside a crystal growth chamber and nitrogen gas, the process comprising:
preparing a eutectic alloy melt of gallium (Ga);
dipping the seed crystal substrate into the eutectic alloy melt, the seed crystal substrate having a catalytic metal having a mesh, stripe, or open polka-dot pattern deposited thereon, the seed crystal substrate including a crystal layer composed of a nitride including at least gallium (Ga), aluminum (Al), or indium (In); and
graphoepitaxially growing a single crystal film of the gallium-containing nitride on the surface of the seed crystal substrate by the reaction at the surface of the seed crystal substrate between gallium, which is a component of a eutectic alloy, and nitrogen dissolving into the eutectic alloy melt from a space zone containing a nitrogen supply source above a surface of the melt.

2. The process for producing the single crystals of the gallium-containing nitride according to claim 1, wherein the catalytic metal is platinum (Pt) and/or iridium (Ir).

3. The process for producing the single crystals of the gallium-containing nitride according to claim 1, wherein at least one metal selected from the group consisting of aluminum (Al), indium (In), ruthenium (Ru), rhodium (Rh), palladium (Pd), rhenium (Re), osmium (Os), bismuth (Bi), and gold (Au) forms the eutectic alloy melt with gallium (Ga).

4. The process for producing the single crystals of the gallium-containing nitride according to claim 1, wherein the pressure in the space zone containing the nitrogen supply source is 0.1 to 0.15 MPa.

5. The process for producing the single crystals of the gallium-containing nitride according to claim 1, wherein the nitrogen supply source is nitrogen, NH4, or nitrogen-containing compound gas.

6. The process for producing the single crystals of the gallium-containing nitride according to claim 1, wherein the seed crystal substrate is sapphire single crystals.

7. (canceled)

8. The process for producing the single crystals of the gallium-containing nitride according to claim 1, wherein a single crystal thin film of a gallium-containing nitride represented by AlxGa1-x-yInyN (0<x<1, 0<y<1, 0<x+y<1) is grown from the eutectic alloy melt of gallium or by further dissolving aluminum (Al) and indium (In) in Ga.

9. The process for producing the single crystals of the gallium-containing nitride according to claim 1, wherein the seed crystal substrate is attached to a lower end portion of a rotating/vertical drive shaft and crystals are grown while rotating the seed crystal substrate.

10. The process for producing the single crystals of the gallium-containing nitride according to claim 1, wherein the crystal growth chamber is of a vertical type in which at least two temperature zones with different temperatures in the vertical direction of the chamber are formed, and the seed crystal substrate is pulled up by the vertical drive shaft to position the seed crystal substrate in a low-temperature zone to allow crystals to grow.

11. The process for producing the single crystals of the gallium-containing nitride according to claim 1, wherein a metal that forms an eutectic alloy with gallium (Ga) and a Ga supply source are placed in a reactor and heated and melted in the reactor at a temperature 100° C. to 150° C. higher than the eutectic temperature to prepare the eutectic alloy melt.

12. The process for producing the single crystals of the gallium-containing nitride according to claim 1, wherein the thickness of the single crystal film of the gallium-containing nitride is 100 to 200 μm.
